(19) United States
(12) Patent Application Publication
(10) Pub. No.: US 2026/0073115 A1
(43) Pub. Date: Mar. 12, 2026

(54) FABRICATION LAYOUT RETARGETING

(71) Applicants: SAMSUNG ELECTRONICS CO., LTD., Suwon-si (KR); The Board of Trustees of the Leland Stanford Junior University, Stanford, CA (US)

(72) Inventors: Sooyong Lee, Menlo Park, CA (US); Gordon Wetzstein, Palo Alto, CA (US); Guandao Yang, Palo Alto, CA (US); Seongtae Jeong, Suwon-si (KR); Suyeon Choi, Redwood City, CA (US)

(21) Appl. No.: 19/214,954

(22) Filed: May 21, 2025

Related U.S. Application Data
(60) Provisional application No. 63/692,536, filed on Sep. 9, 2024.

(51) Int. Cl. G06F 30/392; G06F 30/27; G06N 3/045; G06N 3/08

(52) U.S. Cl. CPC G06F 30/392; G06F 30/27; G06N 3/045; G06N 3/08

(57) ABSTRACT

A method includes: obtaining layout data representing a candidate device fabrication pattern; generating an embedding of the layout data; providing the embedding of the layout data as input to a deep learning model; obtaining, as an output of the deep learning model, a predicted fabricated structure formed using the candidate device fabrication pattern; and adjusting the layout data by backpropagation based on a gradient of a loss function representing a difference between the predicted fabricated structure and a target structure.

### CROSS-REFERENCE TO RELATED APPLICATION

This application claims the benefit of the filing date of U.S. Provisional Application No. 63/692,536, filed on Sep. 9, 2024. The entirety of the foregoing application is incorporated herein by reference.

### BACKGROUND

Fabrication layouts for device fabrication (e.g., electronic and optical device fabrication) indicate patterns that are to be formed on a chip. For example, a layout may include a large number of polygons that represent shapes of device structures. The polygons can be formed on an optical mask (or photomask) and used for lithography on the chip. Due to optical effects (e.g., diffraction) and other non-idealities, such as non-idealities associated with pattern etching, patterns actually formed on the chip differ from the layout patterns of the photomask. Optical proximity correction (OPC) can be used to compensate for some non-idealities.

### SUMMARY

Some aspects of this disclosure relate to a method that includes: obtaining layout data representing a candidate device fabrication pattern; generating an embedding of the layout data; providing the embedding of the layout data as input to a deep learning model; obtaining, as an output of the deep learning model, a predicted fabricated structure formed using the candidate device fabrication pattern; and adjusting the layout data by backpropagation based on a gradient of a loss function representing a difference between the predicted fabricated structure and a target structure.

This and other methods described herein can have one or more of at least the following characteristics.

In some implementations, generating the embedding of the layout data includes applying a relative coordinate encoding to a position of a first feature in the candidate device fabrication pattern. The relative encoding represents a relative position of the first feature in relation to a position of a second feature in the candidate device fabrication pattern.

In some implementations, the relative encoding removes absolute position information from the layout data.

In some implementations, the relative coordinate encoding represents a plurality of relative positions of the first feature in relation to a plurality of corresponding features in the candidate device fabrication pattern. The plurality of corresponding features are selected, as a subset of a set of candidate features in the candidate device fabrication pattern, using a position-based mask with respect to the first feature.

In some implementations, the predicted fabricated structure includes a predicted dimension, and adjusting the layout data includes iteratively adjusting the layout data until a difference between the predicted dimension and a target dimension of the target structure is less than a threshold value.

In some implementations, the layout data represents a plurality of polygons of the candidate device fabrication pattern. The embedding of the layout data is configured such that a predicted fabricated dimension of a first polygon of the plurality of polygons, in the output of the deep learning model, is based on at least one of (i) a distance between the first polygon and a second polygon of the plurality of polygons or (ii) a dimension of the second polygon.

In some implementations, the layout data represents a plurality of polygons of the candidate device fabrication pattern. The deep learning model is configured to jointly process the layout data representing the plurality of polygons.

In some implementations, the predicted fabricated structure includes a predicted polygon dimension, and the loss function represents a difference between the predicted polygon dimension and a target polygon dimension of the target structure.

In some implementations, adjusting the layout data includes adjusting a dimension of a polygon of the layout data.

In some implementations, the deep learning model includes a two-dimensional position-based mask configured to, for each feature of a plurality of features in the candidate device fabrication pattern, exclude connections between the feature and features that are beyond a defined distance from the feature.

In some implementations, the deep learning model is configured to process the embedding of the layout data patch-wise based on a plurality of patches representing distinct two-dimensional areas of the candidate device fabrication pattern. For each feature of the plurality of features, the defined distance is less than a dimension of a patch that includes the feature.

In some implementations, the deep learning model includes an attention mechanism that incorporates the two-dimensional position-based mask.

In some implementations, the deep learning model is configured to process the embedding of the layout data patch-wise based on a plurality of patches representing distinct two-dimensional areas of the candidate device fabrication pattern. At least one of the plurality of patches includes multiple distinct polygons in the candidate device fabrication pattern.

In some implementations, the deep learning model is configured to generate a predicted fabricated structure for a first patch of the plurality of patches based on (i) at least one feature in the first patch and (ii) at least one feature in a second patch of the plurality of patches, the second patch adjacent to the first patch.

In some implementations, adjusting the layout data includes iteratively adjusting layout data for a first patch of the plurality of patches. Iteratively adjusting the layout data for the first patch includes periodically adjusting layout data for a second patch of the plurality of patches, wherein the second patch is adjacent to the first patch.

In some implementations, generating the embedding includes applying a dimensional embedding to a dimension of a first feature in the candidate device fabrication pattern. The dimensional embedding applied to the dimension of the first feature is based on a dimension of a second feature in the candidate device fabrication pattern.

In some implementations, the layout data directly represents a shape of a polygon in the candidate device fabrication pattern.

In some implementations, the method includes at least one of: manufacturing a photomask based on the adjusted layout data, or photolithographically forming a pattern on a chip based on the adjusted layout data.

In some implementations, the deep learning model includes a transformer.

Some aspects of this disclosure relate to a method that includes: obtaining (i) layout data representing a device fabrication pattern and (ii) experimental data characterizing device structures fabricated on a substrate using the layout data; and based on the layout data and the experimental data, training a deep learning network by backpropagation based on a gradient of a loss function representing differences between (i) device structures predicted by the deep learning network based on the layout data and (ii) the device structures of the experimental data.

This and other methods described herein can have one or more of at least the following characteristics.

In some implementations, the deep learning network includes a relative coordinate encoding configured to represent a relative position of a first feature in the device fabrication pattern in relation to a position of a second feature in the device fabrication pattern.

In some implementations, the deep learning network includes a two-dimensional position-based mask configured to, for each feature of a plurality of features in the device fabrication pattern, exclude connections between the feature and features that are beyond a defined distance from the feature.

The foregoing and other methods described herein can be implemented as a system including: at least one processor; and a non-transitory storage medium storing instructions that, when executed by the at least one processor, cause the at least one processor to perform the methods.

### BRIEF DESCRIPTION OF THE DRAWINGS

FIG. 1 is a diagram illustrating retarget workflows.

FIG. 2 is a diagram illustrating layouts.

FIG. 3 is a diagram illustrating an example of a deep learning network.

FIG. 4 is a diagram illustrating an example of a transformer encoder of a deep learning network.

FIG. 5 is a diagram illustrating an example of a relative coordinate encoding (RCE) of a deep learning network.

FIG. 6 is a diagram illustrating an example of an attention mechanism of a deep learning network.

FIG. 7 is a diagram illustrating examples of a position-based mask and patches applied in a deep learning network.

FIG. 8 is a diagram illustrating an example of an end-to-end design and fabrication process.

FIG. 9 is a diagram illustrating an example of an inference process for layout adjustment.

FIG. 10 is a diagram illustrating an example of layout adjustment.

FIG. 11 is a diagram illustrating an example of a processing for training a deep learning network for layout adjustment.

FIG. 12 is a diagram illustrating an example of a computer system.

FIG. 13 is a diagram illustrating an example of a computer system.

### DETAILED DESCRIPTION

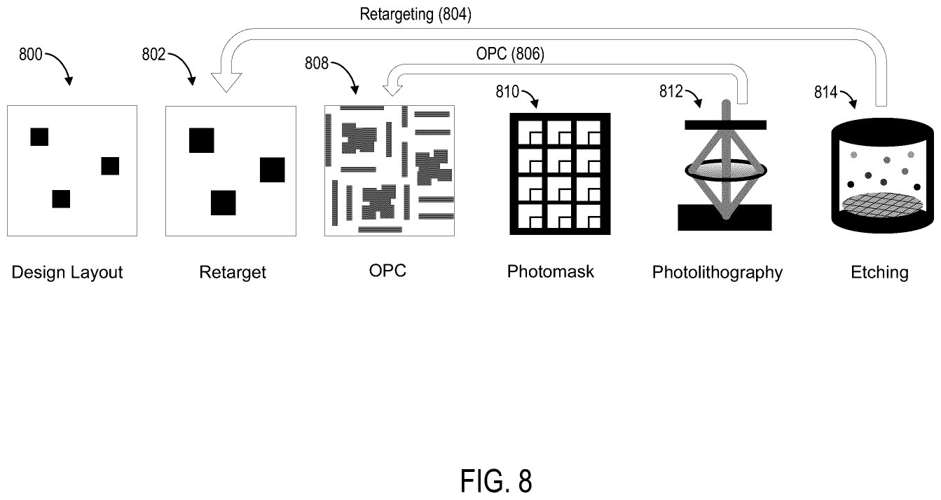

Correction procedures are used to compensate for non-idealities and subtle effects in photolithography and other aspects of device fabrication. As shown in FIG. 8, in an example of a design and device fabrication process, an initial design layout 800 corresponds to a target pattern to be formed on a substrate (e.g., a semiconductor wafer or chip). In this example, the pattern is a set of three squares. Retargeting (804) is performed based on predicted and/or measured differences between the initial design layout 800 and patterns formed on the substrate by etching (814). As a result, a retargeted layout 802 is obtained as an adjustment of the initial design layout 800, e.g., with difference feature sizes, spacings, widths, and/or the like compared to the initial design layout 800. This adjustment can compensate, for example, for etching biases. Optical proximity correction (OPC) is performed on the retargeted layout 802 (806) to obtain an OPC layout 808 that is altered to account for optical distortion, diffraction, and other optical effects that may occur in photolithography (812). The OPC layout 808 can be formed on a photomask (810) and used for subsequent device fabrication.

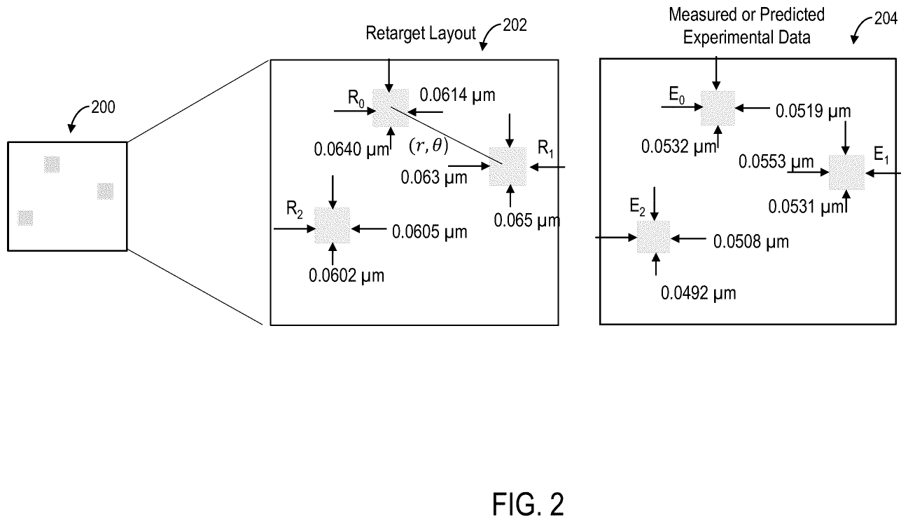

FIG. 2 illustrates an example of process deviation. A pattern of features 200 (in this example, a set of three squares) has a target feature dimension of 0.05 μm (50 nm). However, a design layout with features having 50 nm dimensions will not result in 50 nm features actually being fabricated. Rather, a retarget layout 202 is generated with larger feature sizes, e.g., about 60 nm. The retarget layout 202, when applied in a fabrication process, or when processed by a deep learning network as described herein, will result in a measured or predicted pattern 204 having dimensions smaller than those of the retarget layout 202 and, in this case, closer to the target dimension of 50 nm. In retargeting, dimensions of features in the retarget layout 202 are iteratively adjusted to more-accurately achieve the target dimension.

Existing machine learning-based methods for applying machine learning to retargeting may be hampered by technical limitations associated with machine learning networks. For example, existing methods may rely on non-differentiable approaches associated with relatively poor optimization of device features.

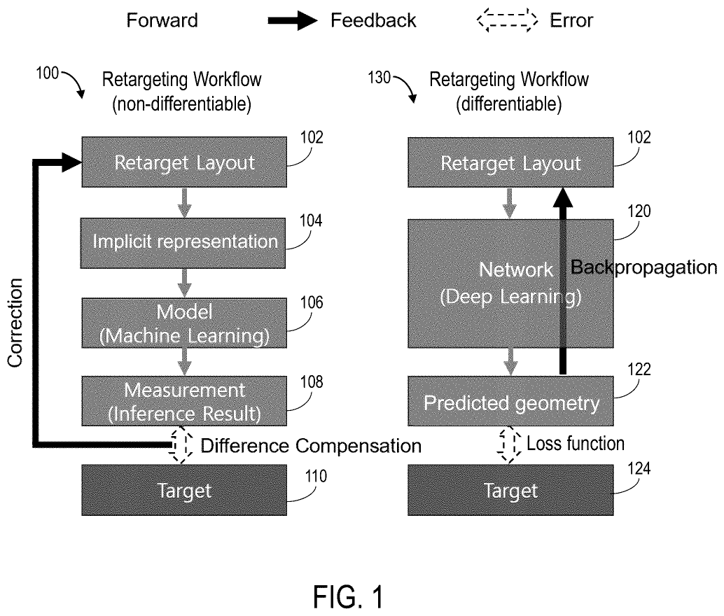

For example, as shown in FIG. 1, a non-differentiable retargeting workflow 100 may include obtaining a retarget layout 102 (a layout to be retargeted) and determining an implicit representation 104 of the retarget layout 102. For example, the implicit representation 104 may be based on a signed distance function. Determining the implicit representation 104 may include extracted geometric features such as density, Gaussian-weighted density, and/or a vector summation from the retarget layout 102. A machine learning model 106 takes the implicit representation 104 as input and outputs an inference result 108 that, based on a comparison with a target result 110, is used for optimization of the implicit representation 104. The optimized implicit representation 104 is then used to determine an adjustment of the retarget layout 102.

However, this approach may be limited by several technical challenges associated with the use of machine learning networks. First, the workflow 100 is non-differentiable, such that gradient-based methods such as backpropagation cannot be applied to adjust the retarget layout 102. For example, the use of the implicit representation 104 may result in non-differentiable evaluation results. The numerical sets of the implicit representation 104 can be optimized using machine learning, but the reverse process-mapping an optimized implicit representation back to a layout—may be difficult or impossible. This limitation makes the process non-differentiable and prevents the use of gradient-based optimization.

In comparison, some implementations of the processes described herein are differentiable. As such, gradient-based optimization, backpropagation, and the use of associated machine learning structures (e.g., transformer and other neural networks) can be used, in some implementations providing significantly improved inference (e.g., more accurate prediction of feature dimensions) and/or may execution in a more computationally efficient manner. In comparison, the non-differentiable approach may be relatively deficient in terms of performance.

Second, the workflow 100 may be generally limited to consideration of individual geometrical features on a feature-by-feature basis, ignoring the influence of neighboring patterns on one another. However, it is known that fabrication (e.g., etching and photolithography) of patterns is affected by the presence and characteristics of nearby patterns. As such, the workflow 100 may fail to accurately perform retargeting in the context of neighboring patterns.

Third, because the workflow 100 is limited to optimization of the implicit representation 104 of features of the retarget layout 102, the workflow 100 may provide less accurate prediction than alternatives that operate on the actual layout geometry.

Some implementations according to this disclosure provide techniques for applying backpropagation to retargeting, e.g., using a transformer network, neural network, or other suitable machine learning network. In some implementations, the described machine learning networks have specific architectures that allow backpropagation to be applied to layout data. For example, particular encodings, masking techniques, patch techniques, and/or attention methods can be applied to resolve technical problems associated with the use of machine learning networks for these purposes. As a result, prediction performance can be improved to obtain layouts that more accurately transfer desired patterns to substrates for electrical, optical, and other applications.

FIG. 1 illustrates an example of a differentiable retargeting workflow 130 according to some implementations of the present disclosure. The retargeting workflow 130 provides a retarget layout 102 (or an encoded version thereof, as discussed below) to a deep learning network 120, which outputs a predicted geometry 122 of features represented by the retarget layout 102, if the features were fabricated using the retarget layout 102. For example, the deep learning network 120 can output predicted dimensions (e.g., lateral dimensions such as width and/or length) of one or more features. The predicted geometry 122 is compared to a target geometry 124 (e.g., target dimension(s)) to derive a loss function indicative of a difference between the predicted geometry 122 and the target geometry 124. A gradient-based method is applied to adjust the retarget layout 102 based on the loss function, e.g., backpropagation is applied to adjust one or more parameters of the retarget layout 102, such as feature dimension(s) and/or relative feature position(s). Accordingly, the geometry of the retarget layout 102 (e.g., geometry directly representative of polygons, such as shape and/or dimension) can be directly optimized. This workflow 130 can be iterated to arrive at a retarget layout 102 that results in a predicted geometry 122 accurately matching the target geometry 124.

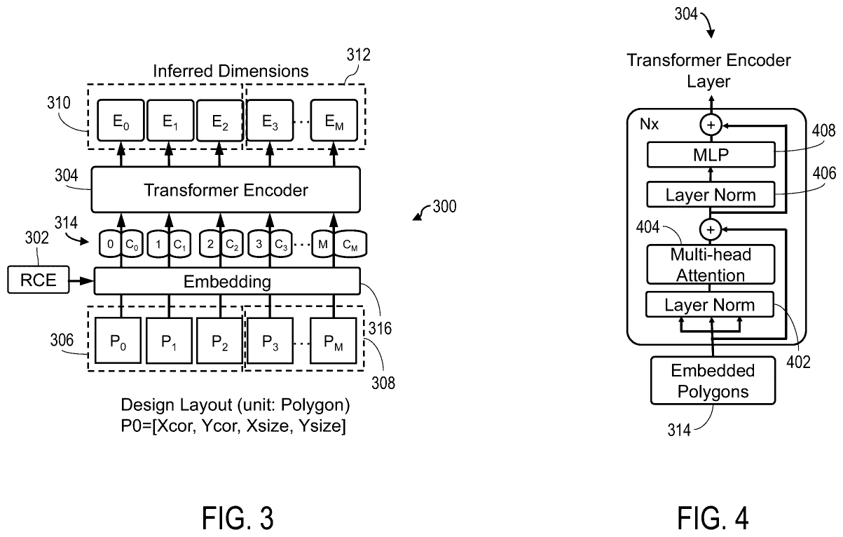

As noted briefly above, the deep learning network 120 can have an architecture that allows for, or improves, the use of the deep leaning network 120 for accurately and efficiently outputting the predicted geometry 122. An example of such a deep learning network 300 is shown in FIG. 3, and elements of the deep learning network 300 are shown in more detail in FIGS. 4-6. The deep learning network 300 includes a relative coordinate encoding (RCE) 302 and a transformer encoder (or transformer encoder layer) 304. The configuration of these elements is discussed below in more detail. Except where noted otherwise, the deep learning network 300 and elements thereof (e.g., the various operations and modules illustrated in FIGS. 3-6) can be configured as described for corresponding elements in Vaswani et al., “Attention Is All You Need,” Proceedings of the 31st International Conference on Neural Information Processing Systems (NIPS '17), the entirety of which is incorporated herein by reference.

Operations, modules, and elements of the deep learning network 300, as illustrated in FIGS. 3-6, can be implemented as software, hardware, or a combination thereof. For example, the deep learning network 300 may be implemented as software executed by a processing included in a computing device or computing system, such as the computing systems 1200, 1300.

As shown in FIG. 3, input to the deep learning network 300 is based on multiple features 306, 308 (P₀, P₁, . . . , Pₘ), which are input tokens of the deep learning network 300. Data representing each feature Pi is included in layout data, e.g., the retarget layout 102. For example, the layout data can includes a GDS file, or another type of layout file, representing a pattern that includes the features 306, 308. The layout data can represent the features 306, 308 as two-dimensional features, corresponding to a top-down (or plan) view. The layout data can represent a candidate device fabrication pattern. In some implementations, the features 306, 308 each is, or represents, a corresponding polygon in the candidate device fabrication pattern. The features 306, 308 can be directly representative of specific shapes, dimensions, and/or positions of polygons.

In some implementations, as shown in FIG. 3, the features 306, 308 have a data structure of [Xcor, Ycor, Xsize, Ysize], where Xcor and Ycor are positions of the features 306, 308 and Xsize and Ysize are sizes of the features 306, 308. In this example, the features 306, 308 are rectangles that are fully represented by the foregoing data structure. In some implementations, the data structure of the features includes additional and/or alternative elements to characterize, for example, multiple different types of shapes.

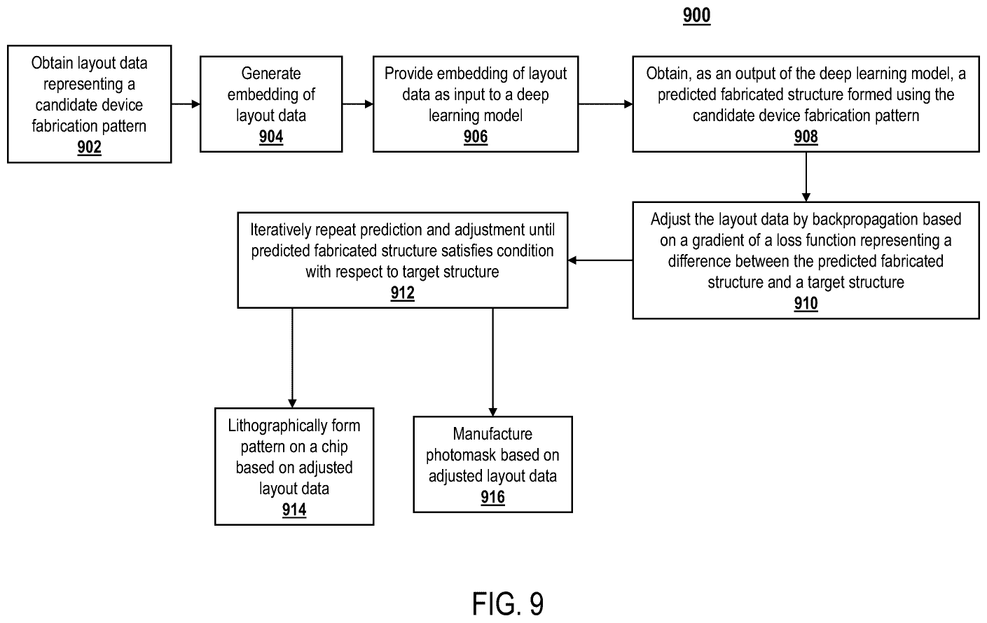

The layout data is described as representing a “candidate” device fabrication pattern because the candidate device fabrication pattern will be evaluated by execution of the deep learning network 300. The candidate device fabrication pattern (as represented by the layout data) is iteratively adjusted until the adjusted candidate device fabrication pattern is predicted to, if applied as a lithography pattern (e.g., photomask pattern, electron beam lithography pattern, or the like), produce a fabricated pattern that satisfies a criteria related to a target pattern. For example, the criteria can include that predicted dimensions of the fabricated structures are sufficiently similar to dimensions of structures of the target pattern, as discussed in reference to FIG. 9 below.

Input of the features 306, 308 to the deep learning network 300 represents processing of a single “patch” of multiple patches that together make up the candidate device fabrication pattern. A given candidate device fabrication pattern may include millions of features, and it may be computationally impractical to perform inference for all features of the pattern at once. Instead, in some implementations, the pattern is divided geometrically into distinct patches (or regions) that are evaluated by (e.g., provided as input to) the deep learning network 300 on a patch-by-patch basis. Each patch can have a dimension (e.g., length and/or width) in a range from 1 μm to 100 μm, and other ranges are also within the scope of this disclosure.

When performing inference on a patch, the deep learning network 300 evaluates, as input, data representing the pattern(s) (e.g., polygon(s)) in the patch. In FIG. 3, this data from the same patch includes features 306 (P₀, P₁, P₂). In some implementations, when performing inference on a patch, the deep learning network 300 evaluates, as input, data representing one or more patterns outside the patch, e.g., in adjacent patches. In FIG. 3, this data from one or more other patches includes features 308 (P₃, . . . , Pₘ). This aspect of the processing is optional, and, in some implementations, only features 306 in a patch for which inference is being performed are provided as input. That is, features 308 may not be included, and in some implementations the deep learning network 300 is not configured to receive the features 308 as input. However, even in this case, feature(s) in patches besides the patch of the features 306 may be incorporated into the inference process, e.g., in the RCE 302 and/or embedding 316.

In some implementations, the patch-based processing includes jointly processing input data corresponding to multiple features. For example, the deep learning network 300 can jointly perform inference for multiple distinct polygons, e.g., jointly predict dimensions of the multiple distinct polygons by receiving, as input, the features 306 that represent multiple distinct polygons. This represents a technical improvement compared to existing retargeting approaches (e.g., existing retargeting approaches) that do not perform gradient-based backpropagation, do not include a relative coordinate encoding, do not implement a position-based mask, do not process inputs in spatial patches, or otherwise differ from implementations of the deep learning networks described herein. For example, the existing retargeting approaches may be limited to consideration of single features one at a time. This may provide worse results than the approaches described herein, because feature prediction may fail to fully account for effects of neighboring features on the evaluated feature.

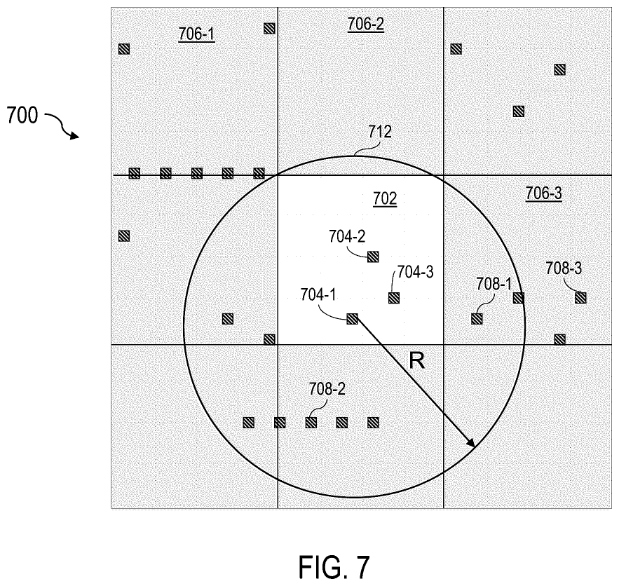

Examples of patches in a device fabrication pattern 700 are shown in FIG. 7 For clarity, only a portion of the device fabrication pattern 700 is shown; it will be understood that, in practice, a pattern may include thousands or millions of patches. An unshaded patch 702 corresponds to a patch on which the deep learning network 300 is executing as part of its patch-wise processing. In this case, the unshaded patch 702 includes three features (e.g., polygons) 704-1, 704-2, 704-3. These features 704-1, 704-2, 704-3 can respectively correspond to P0, P1, and P2 of features 306 in FIG. 3. For example, P₀=[X_{cor,0}, Y_{cor,0}, X_{size,0}, and Y_{size,0}] can indicate a position and size of the polygon of feature 704-1.

Eight patches (e.g., patches 706-1, 706-2, 706-3) are adjacent to patch 702. In some implementations, one or more features of these and/or other (e.g., non-adjacent) patches are included in the features 308 that are taken into account when the deep learning network 300 performs inference on patch 702. For example, as shown in FIG. 3, the features 308 can be provided as input with the features 306. Instead, or additionally, these features can be used when generating embeddings/encodings of the features 306. A masking routine can be used to determine which (if any) of the features in patches besides patch 702 will be used for inference, when patch 702 is being evaluated.

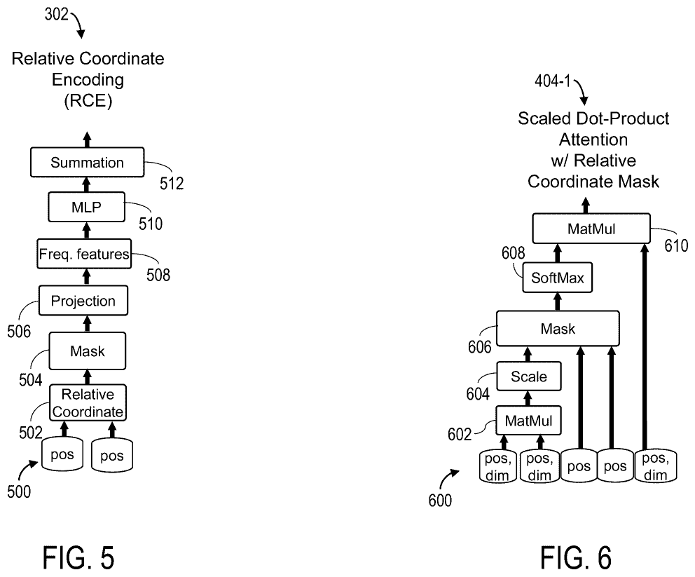

Referring again to FIG. 3, the relative coordinate encoding (RCE) 302 is applied to obtain relative coordinate encodings of the features 306, 308. The RCE 302 (an example of which shown in more detail in FIG. 5) is specially configured to resolve technical challenges associated with the application of deep learning to layout patterns. For purposes of this disclosure, it has been recognized that it may be desirable for processing (e.g., inference) by the deep learning network 300 to be independent, or substantially independent, of how the candidate device fabrication pattern is divided into patches. That is, different splittings of the candidate device fabrication pattern into patches should result in the same or similar inferred dimensions 312 by the deep learning network 300, and, correspondingly, the same or similar adjusted layout data at the end of iterative correction.

To achieve patch independency, in some implementations, the RCE 302 is configured to encode positions of the features 306, 308 into relative positions that characterize the positions of the features 306, 308 with respect to one another. For example, the RCE 302 can be configured to apply relative encodings of the positions in which, for example, a position of feature P₀ is defined relatively with respect to one or more of features P₁, . . . , Pₘ. For example, the relative encoding applied by the RCE 302 can remove absolute position information from the layout data, such that the encoded positions do not include absolute position information. As such, the deep learning network 300 can execute with little or no dependency on how patches are defined.

As an example of the RCE 302, the position [X_{cor,0}, Y_{cor,0}] of feature P₀ can be encoded as RCE₀=Σᵢf((X_{cor,0}−X_{cor,i}), (Y_{cor,0}−Y_{cor,i})), where i corresponds to a summation over other features besides feature P₀, and f corresponds to one or more stages of encoding processing, as discussed below in reference to FIG. 5. In some implementations, i corresponds to a summation over features (e.g., in the same patch as feature P₀ and/or in a different patch) that satisfy a position condition with respect to feature P₀. For example, i can correspond to a summation over features that are within a threshold distance R from the feature P₀. This is an example of a position-based mask applied in the RCE 302 for encoding positions into relative positions.

Based on the RCE 302, the deep learning network 300 can be configured to be differentiable, so that gradient-based backpropagation can be applied for optimization, thereby realizing the computational and accuracy advantages associated with gradient-based backpropagation and deep learning. In addition, based on the RCE 302, the deep learning network 300 can be configured to perform inference based on direct geometric representations of features (e.g., polygon position and dimensions), in comparison to alternative methods that may rely on implicit representations of features, as discussed with respect to FIG. 1. This can allow for the direct optimization of polygon geometry, improving inference results and avoiding the need for feature extraction/implicit representation applied to individual features.

FIG. 7 illustrates an example of a two-dimensional position-based mask. In this discussion, feature 704-1 is taken as feature P₀ in the expression above. A circular mask of radius R (in the two-dimensional space of the layout) is applied so that the relative position encoding of feature 704-1 expresses the relative position of feature 704-1 with respect to features within a distance R from the feature 704-1. This includes, for example, features 704-2, 704-3 in the same patch 702 as feature 704-1, as well as features 708-1, 708-2 in other patches (e.g., adjacent patches). Feature 708-3 is excluded from the relative position encoding of feature 704-1, because feature 708-3 is more than the distance R from the feature 704-1. Accordingly, the mask can represent selection of a subset of features to be used for encoding the position of feature 704-1, the subset being selected from a larger subset of candidate features (e.g., all features of the device fabrication pattern 700, or all features in patch 702 and adjacent patches). In some implementations, the distance R used for the mask of the RCE 302 is less than a dimension (e.g., length and/or width) of the patches, such that the mask effectively restricts the RCE 302 to considering only a given patch and patches adjacent to the given patch, when performing inference for the given patch. The distance R can be referred to as an influence range. The mask can also be applied in one or more other aspects of the deep learning network 300, e.g., for masking 606 in the multi-head attention mechanism 404. The mask can exclude connections or weights between features based on a distance between the features, for example, by setting the connections or weights to 0 or −∞, as appropriate.

The relative coordinate encodings described herein (e.g., RCE 302) represent a technical improvement to deep learning architectures and retargeting. Conventional deep learning approaches may use positional encodings, based on absolute positions, to represent locations of word tokens. However, in a two-dimensional layout, similar designs (e.g., similar geometric patterns) may exist in different locations, but inference should provide consistent results regardless of the absolute location. Therefore, for purposes of this disclosure, it has been recognized that relative coordinate encodings (or relative positional encodings) can provide improved results for deep learning as applied to two-dimensional layouts. Further, the relative coordinate encodings account for experimental data illustrating that the presence of features near a particular feature may affect the etching of the particular feature, e.g., with dependence on the proximity of the nearby features and/or dimensions of the nearby features. Based on the relative coordinate encodings, this physical effect can be efficiently and accurately reflected in inference by the deep learning network 300.

The two-dimensional, position-based masks described herein (e.g., as applied to the attention mechanism, used for relative coordinate encoding, etc.) also represent a technical improvement to deep learning architectures and retargeting. Advantageously, the use of a two-dimensional position-based mask allows the deep learning network 300 to account for the influence of neighboring patterns when performing inference for each patch, regardless of how patches are defined. This reduces the patch-dependency of the deep learning network 300, resolving a technical challenge associated with applying deep learning methods to large layouts that are processed in portions (patches). Further, the position-based mask reduces the computational resources used for execution of the deep learning network 300 by excluding, from the encoding, features that are likely to have little or no influence on the fabrication of the feature under consideration.

FIG. 5 illustrates an example of an architecture, or processing flow, of the RCE 302. As shown in FIG. 5, input feature positions (or coordinates) 500 (e.g., [Xcor, Ycor] for each feature 306, 308)) are provided as input. The position of each feature is made relative with respect to other features (502), e.g., expressed as relative to one or more other features. For example, relative coordinates can be computed as pairwise differences between all position pairs. One or more subsequent operations are performed on the relativized positions, these operations together represented by f in the RCE₀ equation above. In the example of FIG. 5, the operations include masking 504, projection 506, generation of frequency features 508, and processing through a multilayer perceptron (MLP) 510.

The masking 504 can be used to, in the RCE 302, limit incorporation of, or consideration of, positions of other features when determining the encoding of each feature. For example, the masking 504 can mask-out (e.g., set weights or coefficients to 0 or −∞, as appropriate) connections between feature 704-1 and features, such as feature 708-3, that are more than the distance R from the feature 704-1, when performing subsequent operations such as projection 506, generation of frequency features 508, and/or processing using the MLP 510.

Projection 506 can include transforming relative coordinates (e.g., obtained in operation 502) using weights, e.g., fixed weights. In some implementations, projection 506 includes multiplication by the mask of masking 504. Generation of frequency features 508 can include generating frequency-based features based on outputs of projection 506. For example, the outputs of projection 506 can be passed through sine and cosine functions. Processing through the MLP 510 can include processing the frequency features, generated by operation 508, through a suitable linear transformation. The foregoing operations 506, 508, 510 can be performed using known suitable methods of deep learning.

The embeddings obtained by the foregoing processing of FIG. 5 are summed (512) to maintain permutation equivalence. The summation can correspond, for example, to the summation in the RCE₀ equation above.

It will be understood that the operations of FIG. 5 and/or their order can be replaced, omitted, and/or otherwise modified without departing from the scope of this disclosure. Moreover, the disclosed operations need not be performed separately but, rather, can represent functional operations that may be combined, integrated together, and/or functionally replaced without departing from the scope of this disclosure.

As noted above, the use of relative coordinates (502), masking (504), and permutation-equivalent processing (e.g., summation 512) are configurations of the RCE 302 that specifically configure the RCE 302 for processing of layout data, resolving technical challenges associated with patch-based inference and two-dimensional coordinates while accounting for the influences of neighboring features on one another.

Referring again to FIG. 3, an embedding 316 is applied to dimension data of the features 308, 308, to obtain embedded dimensions. For example, in the case where features are represented by vectors [X_{cor}, Y_{cor}, X_{size}, and Y_{size}], a vector [X_{cor}, Y_{cor}] representing feature positions can be encoded by RCE 302 to obtain positional encodings (relative coordinate encodings), and a vector [X_{size}, Y_{size}] representing feature dimensions (in this example, length and width of rectangles) can be embedded using an embedding 316 to obtain embedded dimensions. In some implementations, the embedding 316 includes processing through an MLP to increase a dimension of the dimension data (e.g., from two-dimensional data [X_{size}, Y_{size}] to data with dimension more than two. It will be understood that the embedding 316 can incorporate one or more suitable operations known in deep learning for embedding the dimension data, instead of or in addition to MLP processing.

In some implementations, the embedding 316 of the feature dimension of each feature 306, 308 depends on dimensions of one or more other features (e.g., in the same patch as the feature and/or in another patch). As such, the predicted fabrication of the feature can be based on dimensions of other features, in accordance with experimental data. The embedding 316 can incorporate a position-based mask as described for the RCE 302, e.g., to determine which other feature(s) should be included in the determination of the embedding of each feature.

As a result of the RCE 302 and the embedding 316, embedded polygons 314 are obtained. Each of the embedded polygons 314 corresponds to a feature 306, 308 and can include data Cᵢ that includes or represents (i) the relative coordinate encoding of the feature and (ii) the embedded dimension data of the feature. As shown in FIG. 3, in some implementations, the embedded polygons 314 include indices that indicate the features to which the embedded polygons 314 correspond. Cᵢ in FIG. 3 includes outputs of RCE 302 and embedding 316, e.g., concatenated in a vector form.

The embedded polygons 314 are processed by a transformer encoder (or transformer, or transformer encoder layer) 304. However, the scope of this disclosure is not limited to the use of transformers as deep learning models in the deep learning network 300. Other deep learning model types, such as various suitable types of neural networks and neural radiance field (NeRF) models, can be used in place of the transformer encoder 304 or in addition to the transformer encoder 304. For example, the neural network can be a convolution neural network (CNN), a region efficient convolution neural network (R-CNN), a region proposal network (RPN), a recurrent neural network (RNN), a stacking-based deep neural network (S-DNN), a state-space dynamic neural network (S-SDNN), and/or the like. The relative coordinate encodings, patch-based processing, and masking described herein can equally be used in association with these other deep learning model types to obtain accurate results and realize the benefits described herein as resulting from the relative coordinate encodings, patch-based processing, and masking.

In some implementations, the transformer encoder 304 has a structure as shown in FIG. 4. The transformer encoder 304 is configured to receive, as input, the embedded polygons 314. The embedded polygons 314 are processed using layer normalization 402 and 406, a multi-head attention mechanism 404, and an MLP 408, each of which can be configured according to deep learning methods known in the art. For example, layer normalization 402 and 406 can be performed as described in Ba et al., “Layer normalization,” arXiv preprint arXiv: 1607.06450 (2016), the entirety of which is incorporated herein by reference. The multi-head attention mechanism 404 can be configured as described in Vaswani et al., cited above. As indicated by “Nx,” the transformer encoder 304 can include a stack of multiple sets of elements and operations.

FIG. 6 illustrates an example of an attention mechanism 404-1 of the multi-head attention mechanism 404. Input data 600 derived from the embedded polygons 314 (e.g., as processed using layer normalization 402) is provided as input to the attention mechanism 404-4 that includes matrix multiplication 602, masking 606, a softmax function 608, and matrix multiplication 610. In some implementations, as shown in FIG. 6, the attention mechanism 404-1 is configured to implement scaled dot-product attention as described in Vaswani et al., cited above. In some implementations, as shown in FIG. 6, position and dimension information from the embedded polygons 314 is provided as input to matrix multiplication 602 and/or 610, and/or position information from the embedded polygons 314 is provided as input to masking 606. This configuration of data inputs has been found to provide useful results.

Masking 606 of the attention mechanism 404-1 can mask-out (e.g., set weights or coefficients to 0 or −∞, as appropriate) connections between each feature and features that are more than the distance from the feature, as described in reference to FIG. 7. As such, features that are more than a threshold distance apart from one another can be disconnected for processing by the transformer encoder 304 (or other type of deep learning model, which can equally incorporate masking 606). As discussed above, masking 606 can facilitate inference that reflects the real-world dependence of fabrication results on neighboring features, while limiting consideration of neighboring features to a computationally-feasible extent. It will be understood that the described position-based masking 606 is not limited to use in attention mechanisms of transformers (as in the present example) but, rather, represents a technical improvement that can be applied to deep learning models generally that incorporate connections between layout features. The masking 606 can exclude, or zero-out, connections between feature 704-1 and features, such as feature 708-3, that are more than the distance R from the feature 704-1, when performing matrix multiplication 610 and/or processing using the softmax function 608.

Referring again to FIG. 3, the transformer encoder 304 (or other type of deep learning model) is configured to provide, as output, inferred dimensions 310 of the features 306 in the patch being evaluated. In implementations in which features 308 of one or more other patches are provided as input to the deep learning network 300, the transformer encoder 304 can further output inferred dimensions 312 of the features 308. The inferred dimensions 310, 312 can include, for example, length and/or width. The inferred dimensions 310, 312 represent a prediction of dimensions of features fabricated using the candidate device fabrication pattern represented by the layout data. The inferred dimensions 310, 312 may differ from the dimensions of the features of the layout data based on, for example, etching bias, optical effects, and/or the like. The inferred dimensions 310, 312 can be used for iterative adjustment (retargeting) of the layout data, to obtain layout data that results in target dimensions being fabricated.

In some implementations, the deep learning networks described herein (e.g., deep learning network 300) have permutation equivalence. For example, processing by the deep learning network 300 can be limited to operations with permutation equivalence, such as summation, multiplication, MLP processing, mean value extraction, maximum value extraction, and/or the like. For example, the example of a relative positional encoding RCE₀=Σᵢf((X_{cor,0}−X_{cor,i}), (Y_{cor,0}−Y_{cor,i})) has permutation equivalence, because the summation operation is commutative and operation(s) included in processing f can also have permutation equivalence. As another example, the disclosed masking processes can provide permutation equivalence. In some implementations, based on this configuration, outputs of the deep learning network 300 (e.g., inferred dimensions 310, 312) advantageously have an order matching an order of inputs to the deep learning network 300 (e.g., features 306, 308).

FIG. 9 illustrates an example of a retargeting process 900. The process 900 can be performed, for example, by a computing device or a computing system configured to execute a deep learning network.

The process 900 includes obtaining layout data representing a candidate device fabrication pattern (902). For example, the candidate device fabrication pattern can be a lithographic pattern for fabrication of a nanoelectronic or microlectronic circuit, an optical or optoelectrical device, a micro-electromechanical systems, and/or the like. In some implementations, the candidate device fabrication pattern is a pattern to be formed on a photomask for photolithography. In some implementations, the candidate device fabrication pattern is a pattern to be formed on a substrate (e.g., in one or more layers on a substrate) using electron-beam lithography. The layout data can have any suitable format, e.g., a GDS format.

The process 900 includes generating an embedding of the layout data (904). For example, the embedding can include a relative coordinate encoding (RCE) that represents relative position of features (e.g., polygons) in relation to positions of other features in the candidate device fabrication pattern, as described for RCE 302. The embedding can alternatively or additionally include an embedding of dimension(s) of the features, e.g., a higher-dimensional embedding, as described for embedding 316. In some implementations, the embedding of the position and/or dimension(s) incorporates a position-based mask that excludes connections or weights between features based on a distance between the features, for example, as described with respect to FIG. 7.

The process 900 includes providing the embedding as input to a deep learning model (906). For example, embeddings of features can be provided as input on a patch-by-patch basis, where the deep learning model is configured to simultaneously execute on, or perform inference for, multiple features in the same patch. The deep learning model can have a structure as described for the transformer encoder 304, a neural network structure, etc. The deep learning model (e.g., an attention mechanism of the deep learning model, or another mechanism that is based on connections between features) can include masking that excludes connections or weights between features based on a distance between the features, for example, as described with respect to FIG. 7.

The process 900 includes obtaining, as an output of the deep learning model, a predicted fabricated structure formed using the candidate device fabrication pattern (908). For example, the deep learning model can be configured to output predicted (or inferred) dimensions (e.g., length and/or width) of structures fabricated using the candidate device fabrication pattern, as shown for the inferred dimensions 310, 312 of FIG. 3.

The process 900 includes adjusting the layout data by backpropagation based on a gradient of a loss function representing a difference between the predicted fabricated structure and a target structure (910). Because of the differentiability of the deep learning networks (e.g., embeddings) discussed herein, gradient-based methods can advantageously be applied to update the layout data. For example, the loss function can represent a difference between predicted dimensions and target dimensions. Greater differences can correspond to higher loss, and lower differences can correspond to lower loss. One or more suitable gradient-based iterative adjustment methods can be used, for example, stochastic gradient descent. One or more suitable loss functions can be used, for example, based on a squared difference of corresponding dimensions between the predicted fabricated structure and the target structure, a mean squared error (MSE), and/or the like. Based on numerical differentiability, the adjustment of the layout data by backpropagation (910) can include propagating gradients backward from the output to minimize the loss function. Adjusting the layout data can include adjusting at least one dimension of at least one feature in the layout data. For example, a width and/or a length of a polygon can be adjusted.

In some implementations, during adjustment of the layout data by backpropagation (910), weights and other parameters of the deep learning network are frozen (or fixed), such that loss function optimization is based on modification specifically of the network inputs (layout data).

The process 900 includes iteratively repeating prediction and adjustment until a predicted fabricated structure satisfies a condition with respect to the target structure (912). For example, operations 904, 906, 908, 910 can be iteratively repeated until the condition is satisfied, with each iteration using a newly-adjusted layout data (e.g., updated polygon dimensions). In some implementations, the condition includes a threshold similarity between the predicted fabricated structure and the target structure. For example, iteration can continue until a difference between one or more predicted dimensions of polygons is within a threshold difference from one or more corresponding target dimensions. For example, in some implementations, iteration continues until predicted dimensions of polygons represented by the layout data are within 0.1 nm of target dimensions of the polygons.

The thereby-obtained layout data can be used for fabrication. For example, in some implementations, a pattern on a chip is lithographically formed based on the adjusted layout data (914). For example, a photomask can be manufactured based on the adjusted layout data (916), e.g., with the photomask including polygons having dimensions updated according to the iterative process of operations 902, 904, 906, 908, 910. As an example of a fabrication process, the photomask can be used to perform optical exposure and development on one or more layers on a substrate, following by etching, to obtain device structures represented by the layout data. Based on the improved inference accuracy provided by the deep learning configurations discussed above, the fabricated device structures are expected to more-closely match target device structures than device structures fabricated using alternative retargeting approaches. As another example of a fabrication process, the pattern can be lithographically formed (914) by performing electron-beam lithography according to the adjusted layout data, following by etching. It will be understood that a wide variety of known fabrication methods can be used to fabricate patterns based on the adjusted layout data.

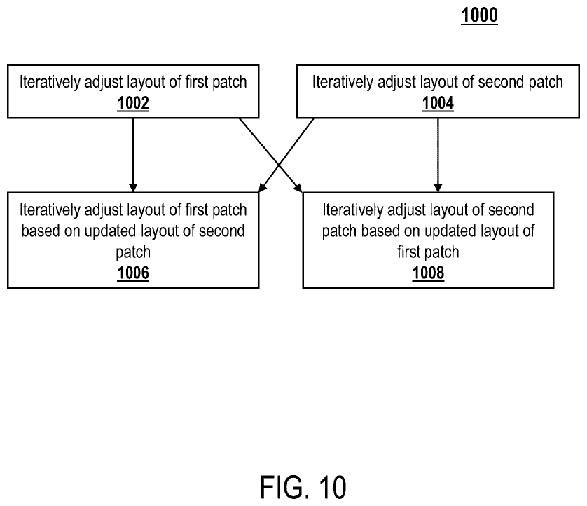

FIG. 10 illustrates an example of a process 1000 of iterative layout adjustment. The process 1000 can be performed, for example, as part of, or in conjunction with, operation 912 of FIG. 9. As shown in FIG. 10, layouts of a first patch (1002) and second patch (1004) are iteratively adjusted, as described for operation 912. For example, a deep learning network as described herein can be iteratively executed to adjust inputs representing polygons of the first patch by backpropagation using gradients, and the deep learning network can also be iteratively executed to adjust inputs representing polygons of the second patch by backpropagation using gradients. In some implementations, iterative adjustment 1002 and iterative adjustment 1004 are performed in parallel, permitting high computational throughput by parallelization.

In some cases, features of the first patch may be near features of the second patch, and/or features of the second patch may be near features of the first patch. For example, the first patch can be adjacent to the second patch. For example, at least one feature from each of the first patch and the second patch may be within the distance R (see FIG. 7) from one another, such that masking (e.g., in the RCE 302, embedding 316, or attention mechanism or other deep learning model mechanism incorporating mask 606) permits connections between the features from the first patch and the second patch. As such, inference for the first patch may depend on structures (e.g., dimensions) features in the second patch, and vice-versa.

In some implementations, updated layouts of different (e.g., adjacent) patches are applied to layout adjustment. For example, as shown in FIG. 10, the updated layout of the second patch (e.g., dimensions of polygons of the second patch), determined by iterative adjustment 1004, is used to further iteratively adjust the layout of the first patch (1006), the updated layout of the first patch (e.g., dimensions of polygons of the first patch), determined by iterative adjustment 1002, is used to further iteratively adjust the layout of the second patch (1008). For example, the embedding 316 of dimensions of features of the first patch can be based on updated dimensions of features of the second patch. In some implementations, for reasons of computational efficiency, adjusted layouts from the second (first) patch are applied to adjustment of the first (second) patch less than once per single iterative adjustment of the first (second) patch. For example, iterative adjustment 1002 of the first patch can be performed n times based on same layout data of the second patch, where n is at least two (e.g., ten). Then, a latest, adjusted version of the layout data of the second patch can be obtained, and iterative adjustment 1006 of the first patch can be performed another n times based on the latest, adjusted version of the layout data of the second patch. As such, iterative adjustment of the layout data for a patch can be performed using repeated meta-iterations that each include multiple iterations of adjustment for the patch, with layout data for one or more other patches adjusted once per meta-iteration.

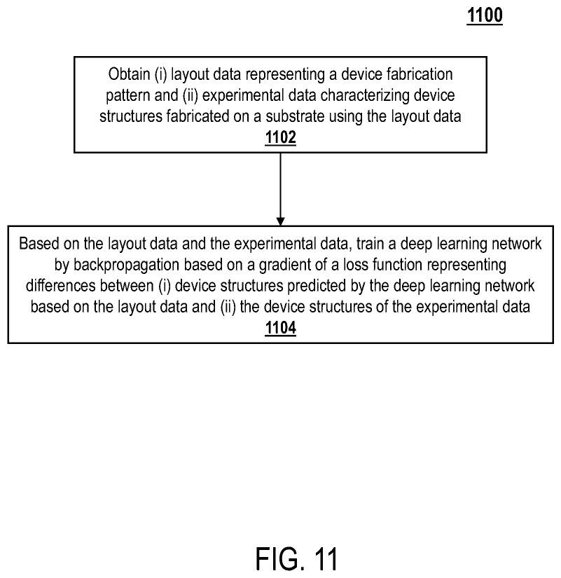

FIG. 11 illustrates an example of a process 1100 for training the deep learning networks described herein, e.g., deep learning network 300. For example, the process 1100 can be used to train a relative coordinate encoding (e.g., RCE 302), an embedding (e.g., embedding 316), and/or a deep learning model such as the transformer encoder 304, a neural network, and/or the like. The process 1100 can be performed by a computer device or computer system.

The process 1100 includes obtaining (i) layout data representing a device fabrication pattern and (ii) experimental data characterizing device structures fabricated on a substrate using the layout data (1102). For example, the layout data can include GDS data or representations/derivatives thereof, or other types of data indicative of polygons to be fabricated on a substrate using lithography. The experimental data can be based on images or other measurements of the device structures. For example, the device fabrication pattern can be used as a photomask to perform photolithography and subsequent etching to form the device structures. The devices structures can be imaged by scanning electron microscopy (SEM) to measure positions and dimensions of the device structures. The experimental data can include the measured positions and dimensions.

The process 1100 includes, based on the layout data and the experimental data, training a deep learning network by backpropagation based on a gradient of a loss function representing differences between (i) device structures predicted by the deep learning network based on the layout data and (ii) the device structures of the experimental data (1104). Training can include adjusting weights, biases, and/or other parameters of one or more elements/operations of the deep learning network. For example, weights and/or biases of one or more of the matrix multiplication(s), multilayer perceptron(s), higher-dimensional embedding(s), normalization(s), function(s), and/or other elements of the deep learning network 300 shown in FIGS. 3-6 can be adjusted. The loss function can be based on, for example, a difference between predicted dimensions of the predicted device structures and measured dimensions of the experimental data.

The adjustment can be performed so as to reduce (e.g., optimize) the loss function using any suitable gradient-based method, e.g., stochastic gradient descent. Because of the differentiability of the machine learning architectures described herein, gradient-based methods can be used to efficiently perform training to obtain highly-accurate deep learning networks. These trained networks can then be applied for inference, e.g., in the process 900.

The deep learning architectures described herein have been found to provide highly accurate and efficient inference of device features for retargeting. Table 1 below illustrates performance of the deep learning network 300 of FIGS. 3-6 in comparison to a conventional Random Forest-based machine learning method and a deep learning method, TabNet, specialized for tabular data. Five million experimental data points were generated with an ideal root mean squared (RMS) deviation of 1 nm, by randomly adding noise to feature dimensions based on the influence of neighboring features. As shown in Table 1, the disclosed deep learning network outputs the two comparative methods by about 7% and exhibits very high accuracy, with only about 1% deviation from the ideal case. These results were achieved using relatively few iterations (e.g., convergence in about 100 iterations), demonstrating the computational advantages associated with deep learning methods such as transformers. As noted above, this disclosure describes specific technical features of deep learning networks that allow deep learning methods to be applied to retargeting so as to achieve these computational advantages.

TABLE 1

| | Random | | Disclosed | |
|---|---|---|---|---|
| | Forest | TabNet | deep learning | |
| | (prior) | (advanced prior) | network | Ideal |
| Normalized | 1.07 | 1.07 | 1.01 | 1.00 |
| Error | | | | |
| RMS (nm) | | | | |

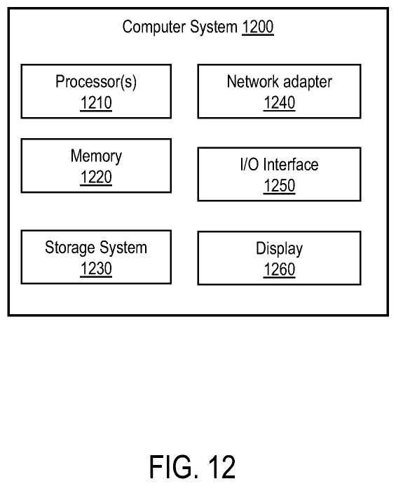

FIG. 12 is a block diagram illustrating a computer system 1200. In some implementations, the computer system 1200 of FIG. 12 is configured to execute the deep learning networks described herein, for example, to perform inference as described with respect to FIG. 9 and/or to perform network training as described with respect to FIG. 11.

The computer system 1200 may refer to any system including a general purpose or special purpose computing system. For example, the computer system 1200 may include a personal computer, a server computer, a laptop computer, a home appliance, and the like. As shown in FIG. 12, the computer system 1200 may include at least one processor 1210, a memory 1220, a storage system 1230, a network adapter 1240, an input/output (I/O) interface 1250, and a display 1260.

The at least one processor 1210 may execute a program module including computer system executable instructions. The program module may include routines, programs, objects, components, logic, data structures, and the like, performing a specific task or implementing a specific abstract data type. The memory 1220 may include a computer system readable, non-transitory medium in the form of a volatile memory such as a random access memory (RAM). The at least one processor 1210 may access the memory 1220 and execute instructions loaded in the memory 1220. The storage system 1230 may non-volatilely store information and may include at least one program product including a program module configured to perform inference and/or training by executing and/or otherwise using the deep learning networks described herein. A program may include, by way of non-limiting examples, an operating system, at least one application, other program modules, and program data.

The network adapter 1240 may provide a connection to a local area network (LAN), a wide area network (WAN), and/or a public network (e.g., the Internet), etc. The I/O interface 1250 may provide a communication channel with a peripheral device such as a keyboard, a pointing device, and an audio system. The display 1260 may output various pieces of information so that the user may check the information.

In some implementations, the processes disclosed above (e.g., data processing operations such as encoding, embedding, and processing using elements of the disclosed deep learning networks, inference as described with respect to FIG. 9, and/or training as described with respect to FIG. 11) are implemented as a computer program product. The computer program product may include a non-transitory computer-readable medium (or storage medium) including computer-readable program instructions for causing the at least one processor 1210 to perform image processing and/or training of models. Computer readable instructions may be, but are not limited to, assembler instructions, instruction set architecture (ISA) instructions, machine instructions, machine dependent instructions, microcode, firmware instructions, state setup data, or source code or object code written in at least one programming language.

The computer-readable medium may be any type of medium capable of non-transitorily holding and storing instructions executed by the at least one processor 1210 or any instruction executable device. The computer-readable medium may be an electronic storage device, a magnetic storage device, an optical storage device, an electromagnetic storage device, a semiconductor storage device, or any combination thereof, but is not limited thereto. For example, the computer readable medium may be a portable computer diskette, a hard disk, a random access memory (RAM), a read-only memory (ROM), an electrically erasable read only memory (EEPROM), a flash memory, a static random access memory (SRAM), a compact disc (CD), a digital versatile disc (DVD), a memory stick, a floppy disk, a mechanically encoded device such as a punch card, or any combination thereof.

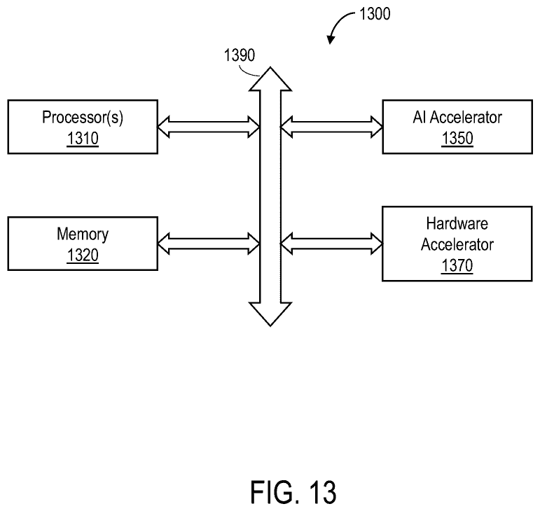

FIG. 13 illustrates another example of a computer system 1300. In some implementations, processes described herein (e.g., those reference in connection to FIG. 12) may be executed in or by the system 1300.

Referring to FIG. 13, the system 1300 may include at least one processor 1310, a memory 1330, an artificial intelligence (AI) accelerator 1350, and a hardware (HW) accelerator 1370, and the at least one processor 1310, the memory 1330, the AI accelerator 1350, and the HW accelerator 1370 may communicate with each other through a bus 1390. In some implementations, the at least one processor 1310, the memory 1330, the AI accelerator 1350, and the HW accelerator 1370 are included in one semiconductor chip. Furthermore, in some implementations, at least two of the at least one processor 1310, the memory 1330, the AI accelerator 1350, and the HW accelerator 1370 are included in two or more semiconductor chips mounted on a board, respectively.

The at least one processor 1310 may execute instructions. For example, the at least one processor 1310 may execute an operating system by executing instructions stored in the memory 1330, or may execute applications executed on the operating system. In some implementations, at least one processor 1310 instructs the AI accelerator 1350 and/or the HW accelerator 1370 to perform a task by executing instructions, and may obtain a result of performing the task from the AI accelerator 1350 and/or the HW accelerator 1370. In some implementations, the at least one processor 1310 is an application specific instruction set processor (ASIP) customized for a specific purpose, and may also support a dedicated instruction set.

The memory 1330 may have an arbitrary structure for storing data. For example, the memory 1330 may include a volatile memory device such as a dynamic random access memory (DRAM) or a static random access memory (SRAM), or a non-volatile memory device such as a flash memory or a resistive random access memory (RRAM). The at least one processor 1310, the AI accelerator 1350, and the HW accelerator 1370 may store data in the memory 1330 or read data from the memory 1330 through the bus 1390.

The AI accelerator 1350 may refer to hardware designed for AI applications. In some implementations, the AI accelerator 1350 includes a neural processing unit (NPU) for implementing a neuromorphic structure, may generate output data by processing input data provided from the at least one processor 1310 and/or the HW accelerator 1370, and may provide the output data to the at least one processor 1310 and/or the HW accelerator 1370. In some implementations, the AI accelerator 1350 is programmable and may be programmed by the at least one processor 1310 and/or the HW accelerator 1370.

The HW accelerator 1370 may refer to hardware designed to perform a specific task at high speed. For example, the HW accelerator 1370 may be designed to perform data transformation such as demodulation, modulation, encoding, and decoding at high speed. The HW accelerator 1370 may be programmable and may be programmed by the at least one processor 1310 and/or the HW accelerator 1370.

In some implementations, the AI accelerator 1350 may execute the deep learning networks described above with reference to the drawings. For example, the AI accelerator 1350 may execute some or all of the inference and/or training tasks described above. The AI accelerator 1350 may generate an output including useful information by processing input parameters, feature maps, and the like. In addition, at least some of the models executed by the AI accelerator 1350 may be executed by the at least one processor 1310 and/or the HW accelerator 1370.

The processes and logic flows described in this document can be performed by one or more programmable processors executing one or more computer programs to perform the functions described herein. The processes and logic flows can also be performed by, and apparatus can also be implemented as special purpose logic circuitry, for example, a Field Programmable Gate Array (FPGA) or an application specific integrated circuit (ASIC).

Processors suitable for the execution of a computer program include, by way of example, both general and special purpose microprocessors, and any one or more processors of any kind of digital computer. Computer readable media suitable for storing computer program instructions and data can include all forms of nonvolatile memory, media and memory devices. The processor and the memory can be supplemented by, or incorporated in, special purpose logic circuitry.

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A method, comprising:
obtaining layout data representing a candidate device fabrication pattern;
generating an embedding of the layout data;
providing the embedding of the layout data as input to a deep learning model;
obtaining, as an output of the deep learning model, a predicted fabricated structure formed using the candidate device fabrication pattern; and
adjusting the layout data by backpropagation based on a gradient of a loss function representing a difference between the predicted fabricated structure and a target structure.

2. The method of claim 1, wherein generating the embedding of the layout data comprises applying a relative coordinate encoding to a position of a first feature in the candidate device fabrication pattern, wherein the relative encoding represents a relative position of the first feature in relation to a position of a second feature in the candidate device fabrication pattern.

3. The method of claim 2, wherein the relative coordinate encoding represents a plurality of relative positions of the first feature in relation to a plurality of corresponding features in the candidate device fabrication pattern,
wherein the plurality of corresponding features are selected, as a subset of a set of candidate features in the candidate device fabrication pattern, using a position-based mask with respect to the first feature.

4. The method of claim 1, wherein the predicted fabricated structure comprises a predicted dimension, and
wherein adjusting the layout data comprises iteratively adjusting the layout data until a difference between the predicted dimension and a target dimension of the target structure is less than a threshold value.

5. The method of claim 1, wherein the layout data represents a plurality of polygons of the candidate device fabrication pattern, and
wherein the embedding of the layout data is configured such that a predicted fabricated dimension of a first polygon of the plurality of polygons, in the output of the deep learning model, is based on at least one of (i) a distance between the first polygon and a second polygon of the plurality of polygons or (ii) a dimension of the second polygon.

6. The method of claim 1, wherein the layout data represents a plurality of polygons of the candidate device fabrication pattern, and
wherein the deep learning model is configured to jointly process the layout data representing the plurality of polygons.

7. The method of claim 1, wherein the predicted fabricated structure comprises a predicted polygon dimension, and
wherein the loss function represents a difference between the predicted polygon dimension and a target polygon dimension of the target structure.

8. The method of claim 1, wherein adjusting the layout data comprises adjusting a dimension of a polygon of the layout data.

9. The method of claim 1, wherein the deep learning model comprises a two-dimensional position-based mask configured to, for each feature of a plurality of features in the candidate device fabrication pattern, exclude connections between the feature and features that are beyond a defined distance from the feature.

10. The method of claim 9, wherein the deep learning model comprises an attention mechanism that incorporates the two-dimensional position-based mask.

11. The method of claim 1, wherein the deep learning model is configured to process the embedding of the layout data patch-wise based on a plurality of patches representing distinct two-dimensional areas of the candidate device fabrication pattern,
wherein at least one of the plurality of patches includes multiple distinct polygons in the candidate device fabrication pattern.

12. The method of claim 11, wherein the deep learning model is configured to generate a predicted fabricated structure for a first patch of the plurality of patches based on (i) at least one feature in the first patch and (ii) at least one feature in a second patch of the plurality of patches, the second patch adjacent to the first patch.

13. The method of claim 1, wherein generating the embedding comprises applying a dimensional embedding to a dimension of a first feature in the candidate device fabrication pattern, wherein the dimensional embedding applied to the dimension of the first feature is based on a dimension of a second feature in the candidate device fabrication pattern.

14. The method of claim 1, comprising at least one of:
manufacturing a photomask based on the adjusted layout data, or
photolithographically forming a pattern on a chip based on the adjusted layout data.

15. The method of claim 1, wherein the deep learning model comprises a transformer.

16. A system comprising:
at least one processor; and
a non-transitory storage medium storing instructions that, when executed by the at least one processor, cause the at least one processor to perform operations comprising:
obtaining layout data representing a candidate device fabrication pattern;
generating an embedding of the layout data;
providing the embedding of the layout data as input to a deep learning model;
obtaining, as an output of the deep learning model, a predicted fabricated structure formed using the candidate device fabrication pattern; and
adjusting the layout data by backpropagation based on a gradient of a loss function representing a difference between the predicted fabricated structure and a target structure.

17. The system of claim 16, wherein generating the embedding of the layout data comprises applying a relative coordinate encoding to a position of a first feature in the candidate device fabrication pattern, wherein the relative encoding represents a relative position of the first feature in relation to a position of a second feature in the candidate device fabrication pattern.

18. A method, comprising:
obtaining (i) layout data representing a device fabrication pattern and (ii) experimental data characterizing device structures fabricated on a substrate using the layout data; and
based on the layout data and the experimental data, training a deep learning network by backpropagation based on a gradient of a loss function representing differences between (i) device structures predicted by the deep learning network based on the layout data and (ii) the device structures of the experimental data.

19. The method of claim 18, wherein the deep learning network comprises a relative coordinate encoding configured to represent a relative position of a first feature in the device fabrication pattern in relation to a position of a second feature in the device fabrication pattern.

20. The method of claim 18, wherein the deep learning network comprises a two-dimensional position-based mask configured to, for each feature of a plurality of features in the device fabrication pattern, exclude connections between the feature and features that are beyond a defined distance from the feature.
